(19) United States
(12) Patent Application Publication
(10) Pub. No.: US 2016/0207762 A1
(43) Pub. Date: Jul. 21, 2016

(54) SENSOR PACKAGE STRUCTURE AND METHOD

(71) Applicant: SIGURD MICROELECTRONICS CORP., SHIN-CHU (TW)

(72) Inventors: CHIH-WEI LU, SHIN-CHU (TW); KUAN-TIEN SHEN, SHIN-CHU (TW); TSAN-LIEN YEH, SHIN-CHU (TW)

(21) Appl. No.: 14/600,256

(22) Filed: Jan. 20, 2015

(51) Int. Cl. B81B 7/00; B81C 1/00

(52) U.S. Cl. CPC B81B 7/0041; B81B 7/008; B81C 1/0023; B81B 2201/0264; B81B 2201/0278; B81B 2201/0214; B81B 2203/0127; B81B 2207/07; B81C 2203/032; B81C 2203/035

(57) ABSTRACT

A sensor package structure and method is characterized in connecting a sensor with a circuit substrate in a flip chip bonding method to enhance the structure strength and miniaturize the product; using a no-flow underfill glue to fill the gap between the sensor and the circuit substrate to protect the contacts of the flip chip structure, prevent the performance from being affected by the overflowing encapsulant, and promote the reliability of products. The present invention uses the no-flow underfill glue process to replace the processes of forming a dam and a soft protection layer and thus simplifies the fabrication process and reduces the fabrication cost.

### BACKGROUND OF THE INVENTION

1. Field of the Invention

The present invention relates to a sensor, particularly to a sensor package structure and method.

2. Description of the Related Art

In the conventional package process of a sensor (such as a pressure sensor), the sensor is tuck to a pre-mold lead frame. Next, the sensor is electrically connected with the lead frame with a wire-bonding process, whereby the signals can be transmitted from the sensor to an external circuit through the lead frame. Next, a lid-attach process and a trim & form (or singulation) process are undertaken to complete the package of the sensor. However, the abovementioned process is not a state-of-the-art package technology—the plastic encapsulation process, which favors mass production. Besides, the lid, which is fixed with insulating glue or in an ultrasonic method, may drop off in fabrication or usage.

In the conventional package process of a sensor, the sensor may be alternatively packaged in the following way: after the sensor has been electrically connected with lead frame with a wire-bonding method, an encapsulation resin is used to wrap the sensor, wires and a portion of the lead frame to form a sensor package.

In the abovementioned two conventional sensor package methods, the sensor is electrically connected with the lead frame with the wire-bonding method. Therefore, the volume of the sensor package seems too large to miniaturize the sensor device.

A Taiwan patent of No. I380413 disclosed a pressure sensor package structure and a fabrication method thereof, wherein the pressure sensor is bonded to a circuit substrate in a flip chip way, and wherein the circuit substrate has an opening, and the sensing region of the pressure sensor is faced to the opening. A dam is formed between the periphery of the pressure sensor and the circuit substrate to prevent resin from overflowing onto the sensing region in the succeeding process. An encapsulation resin is used to wrap the pressure sensor except the sensing region. A soft protection layer (such as a silicone paste) is formed on the sensing region and revealed by the opening. As the prior art must use the dam and the soft protection layer to protect the soldering points and sensing region after flip chip bonding, the package process is somewhat complicated.

### SUMMARY OF THE INVENTION

The primary objective of the present invention is to provide a sensor package structure and method, which fills a no-flow underfill glue into the gap between the sensor and the circuit substrate to completely cover the contacts of the flip chip and protect the contacts against oxidation and humidity, whereby the no-flow underfill glue will prevent the encapsulant from overflowing onto the sensing region lest the function of the sensor be affected.

Another objective of the present invention is to provide a sensor package structure and method, which uses a single process of dispensing or spreading a no-flow underfill glue to replace the process of forming a dam and the process of forming a soft protection layer, whereby the fabrication process is simplified and the manpower and cost is reduced.

To achieve the abovementioned objectives, the present invention proposes a sensor package structure, which comprises a circuit substrate, a plurality of conduction bumps, a sensor, and an encapsulant. The circuit substrate has an opening. The conduction bumps are disposed on the circuit substrate. The sensor has a sensing region facing the opening. The sensor is connected with the surface of the circuit substrate via the conduction bumps. The encapsulant wraps the sensor but reveals the sensing region. The present invention is characterized in having a no-flow underfill glue filled into the gap between the sensor and the circuit substrate and wrapping the conduction bumps.

The present invention also proposes a sensor package method, which comprises steps: providing a circuit substrate having an opening; dispensing or spreading a no-flow underfill glue on the surface of the circuit substrate; providing a sensor having a sensing region; forming a plurality of conduction bumps on the sensor; connecting the sensor with the surface of the circuit substrate via the conduction bumps with the sensing region facing the opening and the no-flow underfill glue filling up the gap between the sensor and the circuit substrate and wrapping the conduction bumps; and forming an encapsulant to wrap the sensor but reveal the sensing region.

The present invention is characterized in using a flip chip bonding technology to connect the sensor with the circuit substrate to enhance the strength of the package structure and miniature the product; filling the gap between the sensor and the circuit substrate with a no-flow underfill glue to wrap the contacts of the flip chip, prevent the succeeding reflow process from affecting the quality of conduction bump soldering, and prevent encapsulant from overflowing and affecting the function of sensor; and omitting the dam and the soft protection layer to simplify the fabrication process and reduce the cost.

Below, embodiments are described in detail in cooperation with the attached drawings to make easily understood the objectives, technical contents, characteristics and accomplishments of the present invention.

### BRIEF DESCRIPTION OF THE DRAWINGS

FIG. 1 is a sectional view schematically showing a sensor package structure according to a first embodiment of the present invention;

FIG. 2 a sectional view schematically showing a sensor package structure according to a second embodiment of the present invention; and

FIGS. 3A-3G are sectional views schematically showing the process of a method for fabricating a sensor package structure of the first embodiment.

### DETAILED DESCRIPTION OF THE INVENTION

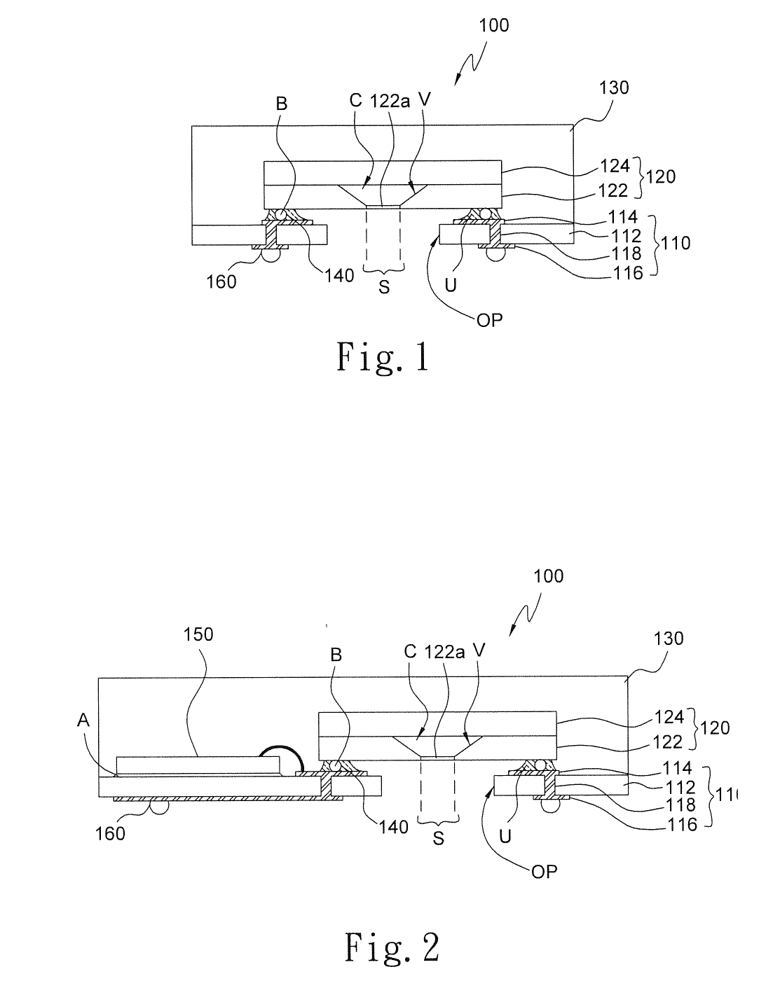

Refer to FIG. 1 a sectional view schematically showing a sensor package structure according to a first embodiment of the present invention.

In the first embodiment of the present invention, the sensor package structure 100 comprises a circuit substrate 110, a plurality of conduction bumps B, a sensor 120, an encapsulant 130 and a no-flow underfill glue U.

The circuit substrate 110 has an opening OP. The circuit substrate 110 is a single layer circuit substrate or a multilayer circuit substrate. In the embodiment shown in FIG. 1, the circuit substrate 110 has a base layer 112, a first circuit layer 114, a second circuit layer 116 and a plurality of conduction channels 118. The first circuit layer 114 and the second circuit layer 116 are respectively disposed on the top surface and the bottom surface of the circuit substrate 110. The conduction channels 112 penetrate the circuit substrate 110 and are electrically connected with the first circuit layer 114 and the second circuit layer 116.

The conduction bumps B are disposed on the first circuit layer 114. The conduction bumps B are made of gold, tin or another suitable material. In the embodiment shown in FIG. 1, each conduction bump B has an organic solderability preservative (OSP) film 140. The conduction bump B and the OSP film 140 combine to form a firm joint point after soldering.

The sensor 120 has a sensing region S and is joined to the first circuit layer 114 of the circuit substrate 110 through the conduction bumps B in a flip chip bonding method with the sensing region S facing the opening OP. In the embodiment shown in FIG. 1, the sensor 120 is an absolute pressure sensor and includes a sensor chip 122 and a piece of glass 124 (or a piece of silicon chip). The sensor chip 122 has a sensing membrane 122a disposed inside the sensing region S. In the embodiment shown in FIG. 1, the sensor chip 122 has a recess V corresponding to the sensing region S. and the sensing membrane 122a is the bottom of the recess V. The sensor chip 122 detects the external environment through the sensing membrane 122a and the opening OP. The glass (or the silicon chip) 124 is stuck to the sensor chip 122 and cooperates with the sensing membrane 122a to form an airtight chamber C. In other embodiments, the sensor 120 may be a temperature sensor or a humidity sensor. In one embodiment, the sensor chip 122 is a single piece of chip.

As shown in FIG. 1, the encapsulant 130 wraps the sensor 120 but reveals the sensing region S.

If the encapsulant 130 covers the sensing region S, the function of the sensor 120 would be affected. In the present invention, the no-flow underfill glue U is filled into the gap between the sensor 120 and the circuit substrate 110, wrapping and protecting the conduction bumps B between the sensor 120 and the circuit substrate 110, preventing the encapsulant 130 from overflowing onto the sensing region S, and protecting the flip-chip contacts between the sensor 120 and the circuit substrate 110 against oxidation and humidity.

In the embodiment shown in FIG. 1, a plurality of conduction balls 160 is disposed on the surface of the second circuit layer 116 and electrically connected with the second circuit layer 116 to facilitate the electric connection between the sensor package 100 and the other electronic device. In one embodiment, the conduction balls 160 are tin balls.

Refer to FIG. 2 a sectional view schematically showing a sensor package structure according to a second embodiment of the present invention. In the second embodiment, an ASIC (Application-Specific Integrated Circuit) chip 150 for processing the detected signals is disposed on and electrically connected with the circuit substrate 110. The ASIC chip 150 is further electrically connected with the sensor 120 through the circuit substrate 110 to receive the signals of the sensor 120. In the embodiment shown in FIG. 2, the ASIC chip 150 is fixed onto the circuit substrate 110 by an adhesion layer A and electrically connected with the first circuit layer 114 in a wire-bonding method. The encapsulant 130 also wraps the ASIC chip 150.

In another embodiment not demonstrated in the drawings, the ASIC chip 150 is fixed on the sensor 120 and electrically connected with the circuit substrate 110 in a wire-bonding method; for example, the ASIC chip 150 is fixed onto the glass (or the silicon chip) 124. In yet another embodiment, the ASIC chip 150 is joined to the circuit substrate 110 in a flip chip bonding method. In a further embodiment, the ASIC chip 150 is disposed on another structure and then electrically connected with the sensor 120.

The method for fabricating the abovementioned sensor package structure 100 will be described in detail below.

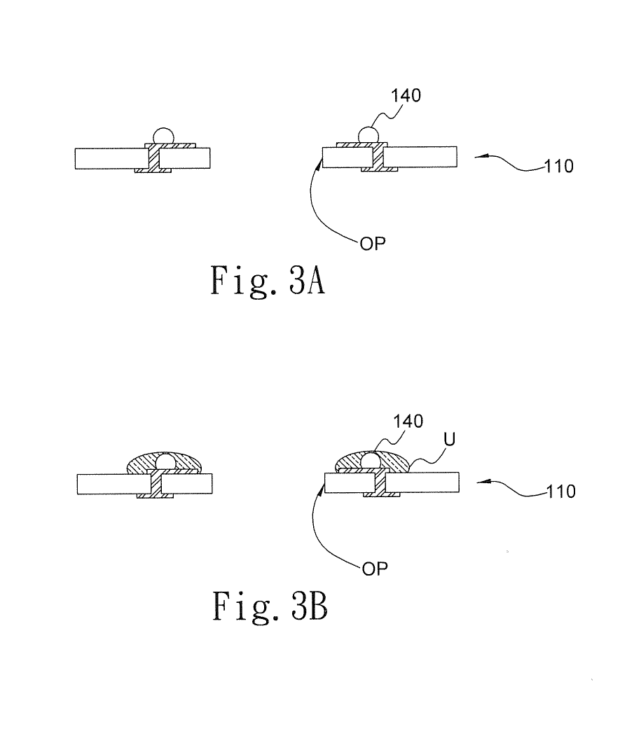

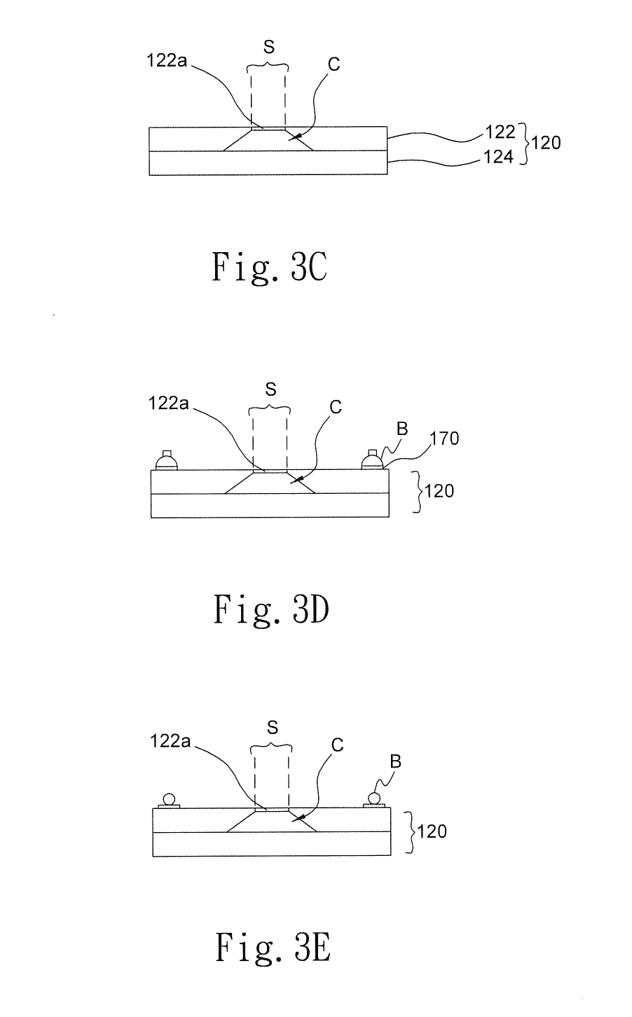

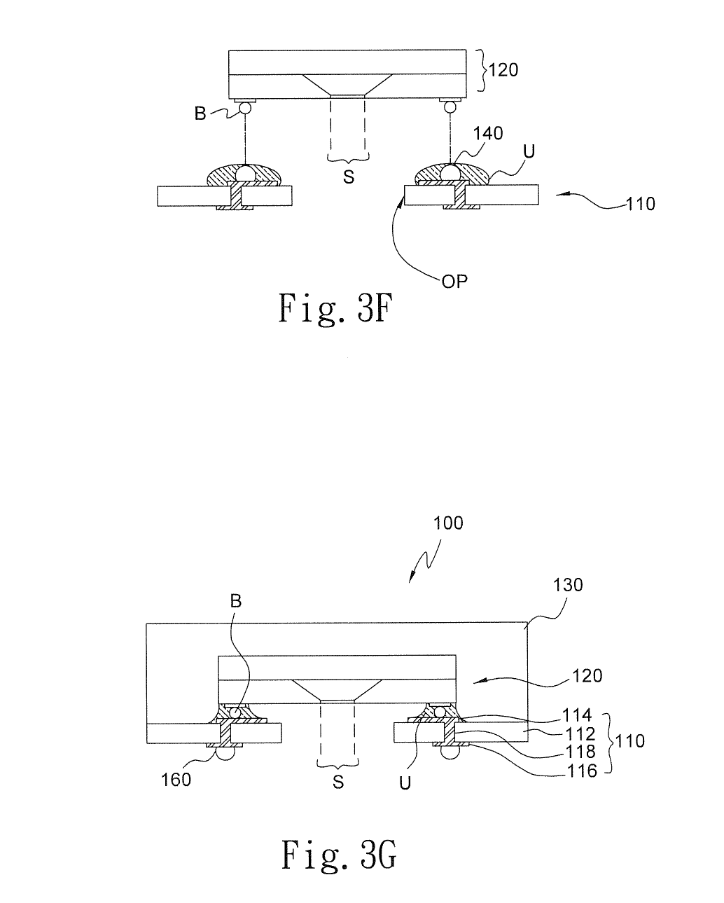

Refer to FIGS. 3A-3G sectional views schematically showing the process of a method for fabricating a sensor package structure of the first embodiment.

Firstly, as shown in FIG. 3A, provide a circuit substrate 110 having a preformed opening OA through which the sensor detects the external environment. Next, before the circuit substrate 110 is packaged, spread OSP film 140 on the surface of the circuit substrate 110 to facilitate the succeeding flip chip bonding process.

Next, as shown in FIG. 3B, dispense or spread a no-flow underfill glue U on the surface of the OSP film 140.

Next, as shown in FIG. 3C, provide a sensor 120 having a sensing region S. Preferably, the sensor 120 is an absolute pressure sensor including a sensor chip 122 and a piece of glass (or a piece of silicon chip) 124. The sensor chip 122 has a sensing membrane 122a in the sensing region S. The glass (or silicon chip) 124 is stuck to the sensor chip 122 and cooperates with the sensing membrane 122a to form an airtight chamber C enabling the sensor 120 to measure the air pressure. In other embodiments, the sensor 120 may be a temperature sensor or a humidity sensor.

Next, as shown in FIG. 3D, form a plurality of conduction bumps B on the sensor 120, wherein an under bump metallization (UBM) layer 170 is formed on the sensor 120 firstly; then, tin bumps or gold bumps are implanted on the UBM layer 170. Alternatively, as shown in FIG. 3E, the gold bumps are formed on the sensor 120 in a stud bump bond (SBB) technology.

Next, as shown in FIG. 3F, use the conduction bumps B to join the sensor 120 to the surface of the circuit substrate 110 in a flip chip bonding method, wherein the conduction bumps B is joined to the OSP film 140, and then a reflow process or a local heating process is used to make the conduction bumps B connect the sensor 120 with the circuit substrate 110, and wherein the sensing region S of the sensor 120 is faced the opening OP. Next, flush and bake the semi-product. In the flip chip bonding process, the no-flow underfill glue U is filled into the gap between the sensor 120 and the circuit substrate 110 to wrap the conduction bumps B and protect the conduction bumps B against oxidation and humidity.

Next, as shown in FIG. 3G, use an encapsulant 130 made of a traditional epoxy resin to wrap the sensor 120 but reveal the sensing region S, wherein the encapsulant 130 is blocked by the no-flow underfill glue U and will not overflow onto the sensing region S. In order to electrically connect the sensor package structure 100 with another electronic device conveniently, a plurality of conduction balls 160 is formed on the surface of the second circuit layer of the circuit substrate 110. Next, undertake a singulation process to complete the process of fabricating the sensor package structure 100.

In one embodiment, before the encapsulant 130 is formed, an ASIC chip 150 is disposed on the circuit substrate 110 and electrically connected with the circuit substrate 110 to integrate the ASIC chip 150 and the sensor 120 in an identical package structure. In the second embodiment shown in FIG. 2, the ASIC chip 150 is electrically connected with the circuit substrate 110 with a wire-bonding method, and the ASIC chip 150 is also electrically connected with the sensor 120 through the circuit substrate 110. In another embodiment not demonstrated in the drawings, the ASIC chip 150 is joined to the circuit substrate 110 in a flip chip bonding method. In a further embodiment, the ASIC chip 150 is fixed on the sensor 120 and electrically connected with the circuit substrate 110 in a wire-bonding method.

In conclusion, the present invention discloses a sensor package structure and method, which uses a flip chip bonding process of a sensor and a circuit substrate to replace the conventional package process so as to enhance the strength of the package structure and miniaturize the product. Further, the present invention uses a no-flow underfill glue to fill the gap between the sensor and the circuit substrate for wrapping and protecting the flip chip contacts, preventing the quality of the soldered conduction bumps from being affected by the succeeding reflow process, and exempting the performance of the sensor from being affected by the overflowing encapsulant. Furthermore, the present invention uses the no-flow underfill glue process to replace the complicated process of forming the dam and the soft protection layer and thus simplifies the fabrication process and reduces the fabrication cost.

The embodiments described above are only to exemplify the present invention but not to limit the scope of the present invention. Any equivalent modification or variation according to the shape, structure, characteristic or spirit of the present invention is to be also included within the scope of the present invention.

What is claimed is:

1. A sensor package structure, which comprises
a circuit substrate having an opening;
a plurality of conduction bumps disposed on a surface of said circuit substrate;
a sensor having a sensing region facing said opening, and joined to said circuit substrate by said conduction bumps in a flip chip bonding method; and
an encapsulant wrapping said sensor but revealing said sensing region,
wherein said sensor package structure is characterized in further comprising a no-flow underfill glue filled into a gap between said sensor and said circuit substrate to wrap said conduction bumps.

2. The sensor package structure according to claim 1, wherein said sensor further comprises
a sensor chip having a sensing membrane located inside said sensing region; and
a piece of glass or silicon chip stuck to a surface of said sensor chip, which is far away from said sensing membrane, and cooperating with said sensing membrane to form an airtight chamber.

3. The sensor package structure according to claim 1 further comprising an organic solderability preservative (OSP) combined with said conduction bumps.

4. The sensor package structure according to claim 1 further comprising an application specific integrated circuit (ASIC) chip disposed on said circuit substrate and electrically connected with said circuit substrate.

5. The sensor package structure according to claim 4, wherein said encapsulant also wraps said ASIC chip.

6. The sensor package structure according to claim 4, wherein said ASIC chip is fixed onto said circuit substrate or said sensor and electrically connected with said circuit substrate in a wire-boning method.

7. The sensor package structure according to claim 4, wherein said ASIC chip is connected with said circuit substrate in a flip chip bonding method.

8. The sensor package structure according to claim 1, wherein said sensor is an absolute pressure sensor, a temperature sensor or a humidity sensor.

9. The sensor package structure according to claim 1 further comprising a plurality of conduction balls disposed on another surface of said circuit substrate.

10. A sensor package method comprising steps:
providing a circuit substrate having an opening;
dispensing or spreading a no-flow underfill glue on a surface of said circuit substrate;
providing a sensor having a sensing region;
forming a plurality of conduction bumps on said sensor;
using said conduction bumps to join said sensor to said surface of said circuit substrate in a flip chip bonding method, wherein said sensing region faces said opening, and wherein said no-flow underfill glue completely fills a gap between said circuit substrate and said sensor and wraps said conduction bumps; and
forming an encapsulant to wrap said sensor but reveal said sensing region.

11. The sensor package method according to claim 10, wherein said sensor includes
a sensor chip having a sensing membrane located inside said sensing region; and
a piece of glass or silicon chip stuck to a surface of said sensor chip, which is far away from said sensing membrane, and cooperating with said sensing membrane to form an airtight chamber.

12. The sensor package method according to claim 10 further comprising a step: spreading an organic solderability preservative (OSP) on said surface of said circuit substrate before dispensing or spreading said no-flow underfill glue.

13. The sensor package method according to claim 10, wherein said conduction bumps are formed in a stud bump bond (SBB) method.

14. The sensor package method according to claim 10, wherein said conduction bumps are formed via forming an under bump metallization (UBM) layer on said sensor and then implanting said conduction bumps.

15. The sensor package method according to claim 10 further comprising a step of reflowing or locally heating said conduction bumps to connect said sensor with said circuit substrate after said sensor is joined to said circuit substrate in said flip chip bonding method.

16. The sensor package method according to claim 10 further comprising a step of disposing an application specific integrated circuit (ASIC) chip on said circuit substrate and electrically connecting said ASIC chip with said circuit substrate before forming said encapsulant.

17. The sensor package method according to claim 16, wherein said encapsulant also wraps said ASIC chip during forming said encapsulant.

18. The sensor package method according to claim 16, wherein said ASIC chip is electrically connected with said circuit substrate in a flip chip bonding method.

19. The sensor package method according to claim 16, wherein said ASIC chip is electrically connected with said circuit substrate via fixing said ASIC chip onto said sensor or said circuit substrate and electrically connecting said ASIC chip with said circuit substrate in a wire-bonding method.

20. The sensor package method according to claim 10, wherein said sensor is an absolute pressure sensor, a temperature sensor or a humidity sensor.

21. The sensor package method according to claim 10 further comprising a step: forming a plurality of conduction balls on another surface of said circuit substrate.
